(19) United States
(12) Patent Application Publication
(10) Pub. No.: US 2014/0174800 A1
(43) Pub. Date: Jun. 26, 2014

(54) EMBEDDED MULTILAYER CERAMIC ELECTRONIC COMPONENT AND METHOD OF MANUFACTURING THE SAME, AND PRINTED CIRCUIT BOARD HAVING EMBEDDED MULTILAYER CERAMIC ELECTRONIC COMPONENT

(71) Applicant: SAMSUNG ELECTRO-MECHANICS CO., LTD., Suwon (KR)

(72) Inventors: Mi Jeong CHANG, Gyunggi-do (KR); Hyun Tae KIM, Gyunggi-do (KR); Byoung Hwa LEE, Gyunggi-do (KR)

(73) Assignee: SAMSUNG ELECTRO-MECHANICS CO., LTD., Suwon (KR)

(21) Appl. No.: 13/935,004

(22) Filed: Jul. 3, 2013

(30) Foreign Application Priority Data
Dec. 21, 2012 (KR) 10-2012-0150860

(51) Int. Cl. H01G 4/232; H05K 1/18

(52) U.S. Cl. CPC H01G 4/2325; H05K 1/185
USPC 174/257; 361/306.3; 174/260; 29/25.41

(57) ABSTRACT

There is provided an embedded multilayer ceramic electronic component, including a ceramic body including dielectric layers, first internal electrodes and second internal electrodes disposed to face each other with the dielectric layers interposed therebetween, a first external electrode electrically connected to the first internal electrodes and a second external electrode electrically connected to the second internal electrodes, and a conductive paste layer formed on the first external electrode and the second external electrode, wherein the first and second external electrodes include a first conductive metal and glass, and the conductive paste layers include a second conductive metal.

### CROSS-REFERENCE TO RELATED APPLICATIONS

This application claims the priority of Korean Patent Application No. 10-2012-0150860 filed on Dec. 21, 2012, in the Korean Intellectual Property Office, the disclosure of which is incorporated herein by reference.

### BACKGROUND OF THE INVENTION

1. Field of the Invention

The present invention relates to an embedded multilayer ceramic electronic component and a method of manufacturing the same, and a printed circuit board having an embedded multilayer ceramic electronic component.

2. Description of the Related Art

As electronic circuits become more highly densified and more highly integrated, mounting spaces provided for passive elements on printed circuit boards have become insufficient. In order to solve this problem, attempts at realizing substrate-embedded components, that is, embedded devices, are being undertaken. In particular, various methods of embedding multilayer ceramic electronic components used as capacitive components in a substrate have been suggested.

In order to embed multilayer ceramic electronic components in a substrate, a method in which a substrate material is used as a dielectric material for the multilayer ceramic electronic component and copper wiring or the like is used as an electrode for the multilayer ceramic electronic component may be used. In addition, in order to realize embedded multilayer ceramic electronic components, there are provided a method in which a high-dielectric polymer sheet or a thin film of dielectric is formed inside the substrate to thereby manufacture the embedded multilayer ceramic electronic component, a method of embedding the multilayer ceramic electronic component in the board, and the like.

Generally, the multilayer ceramic electronic component includes a plurality of dielectric layers formed of a ceramic material and internal electrodes each inserted between the plurality of dielectric layers. An embedded multilayer ceramic electronic component having high capacitance may be realized by disposing such a multilayer ceramic electronic component inside the substrate.

In order to manufacture a printed circuit board including an embedded multilayer ceramic electronic component embedded therein, an upper stacking plate and a lower stacking plate need to be pierced to form a via hole by using a laser to thereby connect a substrate wiring and an external electrode of the multilayer ceramic electronic component, after the multilayer ceramic electronic component is embedded inside a core substrate. This laser process becomes a factor in a significant increase in manufacturing costs of the printed circuit board.

Meanwhile, since the embedded multilayer ceramic electronic component needs to be embedded in a core part inside the substrate, a nickel/tin (Ni/Sn) plating layer is not required on the external electrode, unlike general multilayer ceramic electronic components mounted on a surface of the substrate.

That is, since the external electrode of the embedded multilayer ceramic electronic component is electrically connected to a circuit in the substrate through copper (Cu) vias, a copper (Cu) layer instead of a nickel/tin (Ni/Sn) layer is needed on the external electrode.

Generally, the external electrode contains copper (Cu) as a main component, but may also contain glass. Thus, at the time of a laser process used to form vias in the substrate, components contained in the glass absorb laser energy, which fails to control the process depth of the via.

For this reason, a copper (Cu) plating layer is separately formed on the external electrode of the embedded multilayer ceramic electronic component.

However, since a separate copper (Cu) plating layer is formed, the costs may increase and a deterioration of reliability due to the permeation of a plating solution through an external electrode may still occur, and thus, such defects are required to be solved.

### RELATED ART DOCUMENTS

### Patent Document

### Korean Patent Laid-Open Publication No. 2006-0047733

### SUMMARY OF THE INVENTION

An aspect of the present invention provides an embedded multilayer ceramic electronic component and a method of manufacturing the same, and a printed circuit board having an embedded multilayer ceramic electronic component.

According to an aspect of the present invention, there is provided an embedded multilayer ceramic electronic component, including: a ceramic body including dielectric layers; first internal electrodes and second internal electrodes disposed to face each other with the dielectric layers interposed therebetween; a first external electrode electrically connected to the first internal electrodes and a second external electrode electrically connected to the second internal electrodes; and a conductive paste layer formed on the first external electrode and the second external electrode, wherein the first and second external electrodes include a first conductive metal and glass, and the conductive paste layers include a second conductive metal.

Here, when length of the first and second external electrodes in a length direction of the ceramic body is denoted by A and length of the conductive paste layers in the length direction of the ceramic body is denoted by B, 0.8≦B/A≦1.0 may be satisfied

The first conductive metal may be at least one selected from the group consisting of copper (Cu), silver (Ag), nickel (Ni), and alloys thereof.

The second conductive metal may be copper (Cu).

According to another aspect of the present invention, there is provided a method of manufacturing an embedded multilayer ceramic electronic component, the method including: preparing ceramic green sheets including dielectric layers; forming internal electrode patterns on the ceramic green sheets using a conductive paste for internal electrodes, containing a conductive metal powder and a ceramic powder; laminating the ceramic green sheets having the internal electrode patterns formed thereon, to thereby form a ceramic body including first internal electrodes and second internal electrodes facing each other; forming a first external electrode and a second external electrode on upper and lower surfaces and end parts of the ceramic body, the first and second external electrodes including a first conductive metal and glass; and forming a conductive paste layer of a second conductive metal on the first external electrode and the second external electrode.

Here, when length of the first and second external electrodes in a length direction of the ceramic body is denoted by A and length of the conductive paste layers in the length direction of the ceramic body is denoted by B, 0.8≦B/A≦1.0 may be satisfied.

The first conductive metal may be at least one selected from the group consisting of copper (Cu), silver (Ag), nickel (Ni), and alloys thereof.

The second conductive metal may be copper (Cu).

According to another aspect of the present invention, there is provided a printed circuit board having an embedded multilayer ceramic electronic component, the printed circuit board including: an insulating substrate; and an embedded multilayer ceramic electronic component, the embedded multilayer ceramic electronic component including: a ceramic body including dielectric layers; first internal electrodes and second internal electrodes disposed to face each other with the dielectric layers interposed therebetween; a first external electrode electrically connected to the first internal electrodes and a second external electrode electrically connected to the second internal electrodes; and a conductive paste layer formed on the first external electrode and the second external electrode, wherein the first and second external electrodes include a first conductive metal and glass, and the conductive paste layers include a second conductive metal.

Here, when length of the first and second external electrodes in a length direction of the ceramic body is denoted by A and length of the conductive paste layers in the length direction of the ceramic body is denoted by B, 0.8≦B/A≦1.0 may be satisfied.

The first conductive metal may be at least one selected from the group consisting of copper (Cu), silver (Ag), nickel (Ni), and alloys thereof.

The second conductive metal may be copper (Cu).

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing an embedded multilayer ceramic electronic component according to an embodiment of the present invention;

FIG. 2 is a cross-sectional view taken along line X-X′ of FIG. 1;

FIG. 3 is a view showing a process of manufacturing an embedded multilayer ceramic electronic component according to another embodiment of the present invention; and

FIG. 4 is a cross-sectional view showing a printed circuit board having an embedded multilayer ceramic electronic component according to another embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein.

Rather, these embodiments are provided so that this disclosure will be thorough and complete, and will fully convey the scope of the invention to those skilled in the art.

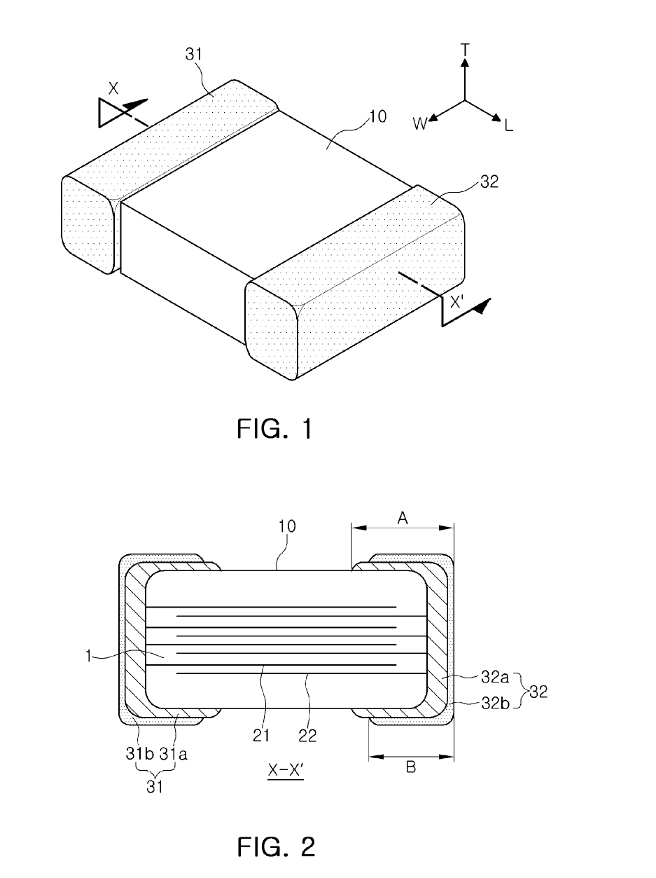

FIG. 1 is a perspective view showing an embedded multilayer ceramic electronic component according to an embodiment of the present invention.

FIG. 2 is a cross-sectional view taken along line X-X′ of FIG. 1.

Referring to FIGS. 1 and 2, an embedded multilayer ceramic electronic component according to an embodiment of the invention may include: a ceramic body 10 including dielectric layers 1; first internal electrodes 21 and second internal electrodes 22 disposed to face each other with the dielectric layers 1 therebetween; a first external electrode 31a electrically connected to the first internal electrodes 21 and a second external electrode 32a electrically connected to the second internal electrodes 22; and conductive paste layers 31b and 32b formed on the first external electrode 31a and the second external electrode 32a, respectively, wherein the first and second external electrodes 31a and 32a include a first conductive metal and glass and the conductive paste layers 31b and 32b may be formed of a second conductive metal.

Hereinafter, the multilayer ceramic electronic component according to an embodiment of the invention, in particular, a multilayer ceramic capacitor, will be described, but the present invention is not limited thereto.

In the multilayer ceramic capacitor according to the embodiment of the invention, a “length direction”, a “width direction”, and a “thickness direction” will be defined as an ‘L’ direction, a ‘W’ direction, and a ‘T’ direction, in FIG. 1. Here, the ‘thickness direction’ may be used to have the same concept as a direction in which the dielectric layers are laminated, that is, a ‘lamination direction’.

In the embodiment of the invention, the shape of the ceramic body 10 is not particularly limited, but may be a hexahedral shape as shown in the drawing.

According to the embodiment of the invention, a raw material for forming the dielectric layer 1 is not particularly limited as long as sufficient capacitance may be obtained therefrom. For example, the raw material may be a barium titanate (BaTiO₃) powder.

As the material for forming the dielectric layers 1, various ceramic additives, organic solvents, plasticizers, binders, dispersants, and the like may be added to the powder, such as the barium titanate (BaTiO₃) powder, or the like, depending on the purpose of the invention.

The average particle diameter of a ceramic powder used in forming the dielectric layer 1 is not particularly limited, and may be controlled in order to achieve the purposes of the invention, for example, to 400 nm or smaller.

A material for the first and second internal electrodes 21 and 22 is not particularly limited. For example, the first and second internal electrodes 21 and 22 may be formed by using a conductive paste composed of at least one of precious metal materials, such as, palladium (Pd), a palladium-silver (Pd—Ag) alloy, and the like, nickel (Ni), and copper (Cu).

According to the embodiment of the invention, external electrodes 31 and 32 may be formed on an outer surface of the ceramic body 10, the external electrodes 31 and 32 including first and second external electrodes 31a and 32a and conductive paste layers 31b and 32b formed on the first and second external electrodes 31a and 32a, respectively.

The first and second external electrodes 31a and 32a may contain a first conductive metal and glass, and the conductive paste layers 31b and 32b may be formed of a second conductive metal.

The first and second external electrodes 31a and 32a may be formed on an outer surface of the ceramic body 10 in order to form capacitance, and may be electrically connected to the first and second internal electrodes 21 and 22.

The first and second external electrodes 31a and 32a may be formed of the same conductive material as the first and second internal electrodes 21 and 22, but are not limited thereto. For example, the first and second external electrodes 31a and 32a may be formed of at least one first conductive metal selected from the group consisting of copper (Cu), silver (Ag), nickel (Ni), and alloys thereof.

The first and second external electrodes 31a and 32a may be formed by coating and firing a conductive paste, which is prepared by adding glass frit to the first conductive metal powder.

According to the embodiment of the invention, the conductive paste layers 31b and 32b of the second conductive metal may be formed on the first external electrode 31a and the second external electrode 32a, respectively.

The second conductive metal is not particularly limited, but may be copper (Cu).

Generally, since the multilayer ceramic capacitor is mounted on a printed circuit board, a nickel/tin plating layer is normally formed on the external electrode.

However, the multilayer ceramic capacitor according to the embodiment of the invention is embedded in the printed circuit board, and is thus not mounted on the substrate. The first external electrode 31a and the second external electrode 32a of the multilayer ceramic capacitor are electrically connected to the circuit of the printed circuit board through copper (Cu) vias.

Therefore, according to the embodiment of the invention, the conductive paste layers 31b and 32b may be formed of copper (Cu), which has excellent electrical connectivity with a material for the vias in the substrate, copper (Cu).

Meanwhile, the first external electrode 31a and the second external electrode 32a contain copper (Cu) as a main component, but also contain glass. Thus, at the time of a laser process used to form the vias formed in the substrate, components contained in the glass absorb laser energy, which fails to control the process depth of the via.

For this reason, a copper (Cu) plating layer is separately formed on the external electrode of the embedded multilayer ceramic electronic component.

However, since the copper (Cu) plating layer is separately formed, the cost may increase and reliability may be deteriorated due to the permeation of a plating solution into the ceramic body.

Therefore, according to the embodiment of the invention, the above defects may be solved by forming the conductive paste layers 31b and 32b of copper (Cu) on the first external electrode 31a and the second external electrode 32a, respectively.

Specifically, the conductive paste layers 31b and 32b may be formed by coating a conductive paste containing copper (Cu) but not containing glass frit on the first external electrode 31a and the second external electrode 32a.

That is, the conductive paste layers 31b and 32b after firing may be characterized by containing only copper (Cu), the second conductive metal.

Therefore, according to the embodiment of the invention, plating-related defects may be solved by coating and firing a conductive paste containing copper (Cu) to form the conductive paste layers on the first external electrode 31a and the second external electrode 32a but not forming plating layers of copper on the first external electrode 31a and the second external electrode 32a.

That is, since the plating layers are not formed on the first external electrode 31a and the second external electrode 32a, problems of an increase in costs due to a plating process and a deterioration in reliability due to permeation of the plating solution into the ceramic body may be solved.

In addition, the conductive paste layers 31b and 32b after firing only contain copper (Cu), a second conductive metal, but do not contain glass frit, and thus, at the time of a laser process used to form vias in the substrate, the components contained in the glass absorb laser energy, failing to control the process depth of the via.

Referring to FIG. 2, when, in the multilayer ceramic electronic component according to the embodiment of the invention, length of the first and second external electrodes 31a and 32a in a length direction of the ceramic body 10 is denoted by A and length of the conductive paste layers 31b and 32b in the length direction of the ceramic body 10 is denoted by B, 0.8≦B/A≦1.0 may be satisfied.

The length (A) of the first and second external electrodes 31a and 32a in a length direction of the ceramic body 10 and the length (B) of the conductive paste layers 31b and 32b in the length direction of the ceramic body 10 may be measured by scanning a scanning electron microscope (SEM) image of a cross section in the length direction of the ceramic body 10 as shown in FIG. 2.

For example, as shown in FIG. 2, on an image obtained by scanning a cross-section in a length-thickness (L-T) direction, which is cut at the central portion in a width (W) direction of the ceramic body 10, using a scanning electron microscope (SEM), the lengths of the first and second external electrodes 31a and 32a and the conductive paste layers 31b and 32b may be measured and obtained.

A ratio of the length (B) of the conductive paste layers 31b and 32b in the length direction of the ceramic body 10 to the length (A) of the first and second external electrodes 31a and 32a in the length direction of the ceramic body 10 may be controlled to satisfy 0.8≦B/A≦1.0, so that a multilayer ceramic capacitor having excellent via process in the substrate and excellent reliability may be realized.

When the ratio of the length (B) of the conductive paste layers 31b and 32b in the length direction of the ceramic body 10 to the length (A) of the first and second external electrodes 31a and 32a in the length direction of the ceramic body 10, B/A, is below 0.8, defects may occur in the via process in the substrate.

Whereas, if the ratio of the length of the conductive paste layers 31b and 32b in the length direction of the ceramic body 10 (B) to the first and second external electrodes 31a and 32a in the length direction of the ceramic body 10 (A), B/A, is above 1.0, the multilayer ceramic capacitor may have reliability defects.

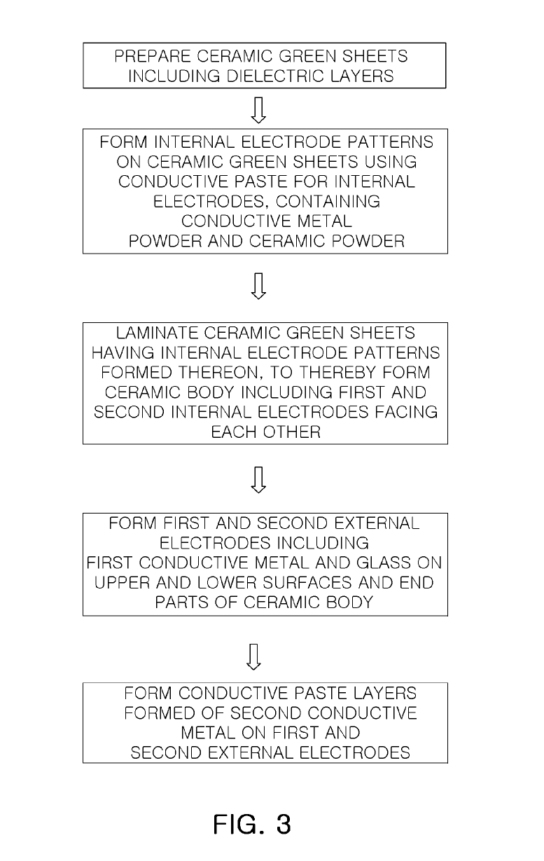

FIG. 3 is a view showing a process of manufacturing an embedded multilayer ceramic electronic component according to another embodiment of the present invention.

Referring to FIG. 3, a method of manufacturing an embedded multilayer ceramic electronic component according to another embodiment of the invention may include: preparing ceramic green sheets including dielectric layers; forming internal electrode patterns on the ceramic green sheets using a conductive paste for internal electrodes, containing a conductive metal powder and a ceramic powder; laminating the ceramic green sheets having the internal electrode patterns formed thereon, to thereby form a ceramic body including first internal electrodes and second internal electrodes facing each other; forming a first external electrode and a second external electrode on upper and lower surfaces and end parts of the ceramic body, the first and second external electrodes including a first conductive metal and glass; and forming conductive paste layers of a second conductive metal on the first external electrode and the second external electrode.

Hereinafter, a method of manufacturing the embedded multilayer ceramic electronic component according to the embodiment of the invention will be described, but the present invention is not limited thereto.

As for the method of manufacturing the embedded multilayer ceramic electronic component according to the embodiment of the invention, first, a slurry prepared by including a powder of barium titanate (BaTiO₃) or the like is coated and dried on a carrier film, to thereby prepare a plurality of ceramic green sheets, whereby dielectric layers may be formed.

The ceramic green sheets may be prepared by mixing a ceramic powder, a binder, and a solvent to prepare the slurry, and molding the slurry into a sheet shape having a thickness of several μm, using a doctor blade method.

Then, a conductive paste for an internal electrode may be prepared, the conductive paste containing 40 to 50 parts by weight of a nickel powder having an average nickel particle size of 0.1 to 0.2 μm.

The conductive paste for an internal electrode was coated on the ceramic green sheets by a screen printing method, to thereby form internal electrodes, and then the resulting structures were laminated in 400 to 500 layers to thereby manufacture a ceramic body 10.

Then, a first external electrode and a second external electrode including a first conductive metal and glass may be formed on upper and lower surfaces and end parts of the ceramic body.

The first conductive metal may be, but is not particularly limited to, at least one selected from the group consisting of copper (Cu), silver (Ag), nickel (Ni), and alloys thereof.

The glass is not particularly limited, and any material that may have the same composition as glass used in manufacturing external electrodes of general multilayer ceramic capacitors may be used.

The first and second external electrodes may be formed on the upper and lower surfaces and end parts of the ceramic body to be electrically connected to the first and second internal electrodes, respectively.

Then, conductive paste layers of a second conductive metal may be formed on the first external electrode and the second external electrode.

The second conductive metal is not particularly limited, but may be copper (Cu).

According to the embodiment of the invention, the conductive paste layers of the second conductive metal may be formed, unlike general embedded multilayer ceramic capacitors in which plating layers are formed on first and second external electrodes.

That is, the conductive paste layers are not formed by a plating process, but may be formed by coating a conductive paste composed of the second conductive metal on the first and second external electrodes of the ceramic body.

As such, since the plating layers are not formed on the first external electrode 31a and the second external electrode 32a, the defects of an increase in costs due to a plating process and deterioration in reliability due to permeation of the plating solution into the ceramic body may be solved.

In addition, the conductive paste layers 31b and 32b after firing contains only copper (Cu), a second conductive metal, but does not contain glass frit, and thus, at the time of a laser process used to form vias in the substrate, the components contained in the glass absorb laser energy, failing to control the process depth of the via.

In addition, according to the method of manufacturing the embedded multilayer ceramic electronic component according to another embodiment of the invention, length of the first and second external electrodes 31a and 32a in the length direction of the ceramic body 10 is denoted by A and length of the conductive paste layers 31b and 32b in the length direction of the ceramic body 10 is denoted by B, 0.8≦B/A≦1.0 may be satisfied.

A ratio of the length (B) of the conductive paste layers 31b and 32b in the length direction of the ceramic body 10 to the length (A) of the first and second external electrodes 31a and 32a in the length direction of the ceramic body 10 may be controlled to satisfy 0.8≦B/A≦1.0, so that a multilayer ceramic capacitor having excellent via process and reliability in the substrate may be realized.

The descriptions of the same features as the foregoing embedded multilayer ceramic electronic component according to the embodiment of the present invention will be omitted.

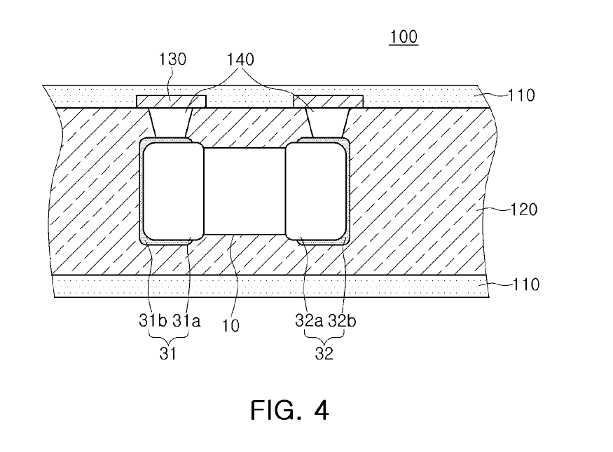

FIG. 4 is a cross-sectional view showing a printed circuit board 100 having an embedded multilayer ceramic electronic component according to another embodiment of the present invention.

Referring to FIG. 4, a printed circuit board 100 having an embedded multilayer ceramic electronic component may include an insulating substrate 110, and an embedded multilayer ceramic electronic component. The embedded multilayer ceramic electronic component includes a ceramic body 10 including dielectric layers 1; first internal electrodes 21 and second internal electrodes 22 disposed to face each other with the dielectric layers 1 therebetween; a first external electrode 31a electrically connected to the first internal electrodes 21 and a second external electrode 32a electrically connected to the second internal electrodes 22; and conductive paste layers 31b and 32b formed on the first external electrode 31a and the second external electrode 32a, wherein the first and second external electrodes 31a and 32a include a first conductive metal and glass and the conductive paste layers 31b and 32b include a second conductive metal.

The insulating substrate 110 may include an insulating layer 120, and, as necessary, may include conductive patterns 130 and conductive via holes 140, constituting various types of interlayer circuits, as illustrated in FIG. 4. This insulting substrate 110 may be a printed circuit board 100 including a multilayer ceramic electronic component therein.

After being inserted in the printed circuit board 100, the multilayer ceramic electronic component is subjected to several severe environments during post processing, such as thermal treatment and the like, in the same manner as the printed circuit board 100.

In particular, shrinkage and expansion of the printed circuit board 100 due to a thermal treatment process are directly transferred to the multilayer ceramic electronic component inserted in the printed circuit board 100, thereby applying stress to an adhesive surface between the multilayer ceramic electronic component and the printed circuit board 100.

When the stress applied to the adhesive surface between the multilayer ceramic electronic component and the printed circuit board 100 is stronger than adhesive strength therebetween, delamination defects in which the adhesive surface is delaminated may occur.

The adhesive strength between the multilayer ceramic electronic component and the printed circuit board 100 is proportional to electrochemical binding force between the multilayer ceramic electronic component and the printed circuit board 100 and effective surface area of the adhesive surface. Therefore, the delamination between the multilayer ceramic electronic component and the printed circuit board 100 may be reduced by controlling the surface roughness of the multilayer ceramic electronic component to increase the effective surface area of the adhesive surface between the multilayer ceramic electronic component and the printed circuit board 100.

In addition, the incidence of delamination of the adhesive surface between the multilayer ceramic electronic component and the printed circuit board 100 depending on the surface roughness of the multilayer ceramic electronic component embedded in the printed circuit board 100 may be confirmed.

Hereafter, the present invention will be described in detail with reference to inventive examples, but is not limited thereto.

### Example

Each embedded multilayer ceramic electronic component of Example was manufactured so as to allow the ratio of the length (B) of the conductive paste layers 31b and 32b in the length direction of the ceramic body 10 to the length (A) of the first and second external electrodes 31a and 32a in the length direction of the ceramic body 10 to satisfy the numerical range according to the embodiment of the present invention.

### Comparative Example

Each embedded multilayer ceramic electronic component of the Comparative Example was manufactured in the same conditions as the above-described example except that the ratio of the length (B) of the conductive paste layers 31b and 32b in the length direction of the ceramic body 10 to the length (A) of the first and second external electrodes 31a and 32a in the length direction of the ceramic body 10 is outside of the numerical range according to the embodiment of the present invention.

Table 1 below showed that, as for the embedded multilayer ceramic electronic components according to the embodiments of the present invention, via processability and reliability were compared depending on the ratio of the length (B) of the conductive paste layers 31b and 32b in the length direction of the ceramic body 10 to the length (A) of the first and second external electrodes 31a and 32a in the length direction of the ceramic body 10.

TABLE 1

| | | Via | Reliability |
|---|---|---|---|
| Sample | B/A | Processability | Evaluation |
| *1 | 1.14 | x | ∘ |
| *2 | 1.06 | x | ∘ |
| 3 | 1.00 | ∘ | ∘ |
| 4 | 0.94 | ∘ | ∘ |
| 5 | 0.88 | ∘ | ∘ |
| 6 | 0.84 | ∘ | ∘ |
| 7 | 0.80 | ∘ | ∘ |
| *8 | 0.76 | ∘ | x |
| *9 | 0.72 | ∘ | x |
| *10 | 0.69 | ∘ | x |

*Comparative Example
x: Poor
∘: Good

It may be seen from Table 1 above that in Samples 1, 2, and 8 to 10 as the Comparative Example, outside of the numerical range of the present invention, via processing was defective or reliability may be problematic.

Whereas, it may be seen that in Samples 3 to 7 as Example, satisfying the numerical range of the present invention, via processability was good and reliability was excellent.

As set forth above, according to the embodiments of the present invention, the conductive paste layers containing copper (Cu) are formed on the external electrodes of the embedded multilayer ceramic electronic component, so that defects in laser processing when via holes are formed in the substrate may be prevented; the deterioration in reliability due to permeation of a plating solution may be prevented; and the costs may be reduced by eliminating the need of a plating process.

While the present invention has been shown and described in connection with the embodiments, it will be apparent to those skilled in the art that modifications and variations may be made without departing from the spirit and scope of the invention as defined by the appended claims.

What is claimed is:

1. An embedded multilayer ceramic electronic component, comprising:
a ceramic body including dielectric layers;
first internal electrodes and second internal electrodes disposed to face each other with the dielectric layers interposed therebetween;
a first external electrode electrically connected to the first internal electrodes and a second external electrode electrically connected to the second internal electrodes; and
a conductive paste layer formed on the first external electrode and the second external electrode,
wherein the first and second external electrodes include a first conductive metal and glass, and the conductive paste layers include a second conductive metal.

2. The embedded multilayer ceramic electronic component of claim 1, wherein, when length of the first and second external electrodes in a length direction of the ceramic body is denoted by A and length of the conductive paste layers in the length direction of the ceramic body is denoted by B, 0.8≦B/A≦1.0 is satisfied

3. The embedded multilayer ceramic electronic component of claim 1, wherein the first conductive metal is at least one selected from the group consisting of copper (Cu), silver (Ag), nickel (Ni), and alloys thereof.

4. The embedded multilayer ceramic electronic component of claim 1, wherein the second conductive metal is copper (Cu).

5. A method of manufacturing an embedded multilayer ceramic electronic component, the method comprising:
preparing ceramic green sheets including dielectric layers;
forming internal electrode patterns on the ceramic green sheets using a conductive paste for internal electrodes, containing a conductive metal powder and a ceramic powder;
laminating the ceramic green sheets having the internal electrode patterns formed thereon, to thereby form a ceramic body including first internal electrodes and second internal electrodes facing each other;
forming a first external electrode and a second external electrode on upper and lower surfaces and end parts of the ceramic body, the first and second external electrodes including a first conductive metal and glass; and
forming a conductive paste layer of a second conductive metal on the first external electrode and the second external electrode.

6. The method of claim 5, wherein, when length of the first and second external electrodes in a length direction of the ceramic body is denoted by A and length of the conductive paste layers in the length direction of the ceramic body is denoted by B, 0.8≦B/A≦1.0 is satisfied

7. The method of claim 5, wherein the first conductive metal is at least one selected from the group consisting of copper (Cu), silver (Ag), nickel (Ni), and alloys thereof.

8. The method of claim 5, wherein the second conductive metal is copper (Cu).

9. A printed circuit board having an embedded multilayer ceramic electronic component, the printed circuit board comprising:
an insulating substrate; and
an embedded multilayer ceramic electronic component,
the embedded multilayer ceramic electronic component including: a ceramic body including dielectric layers; first internal electrodes and second internal electrodes disposed to face each other with the dielectric layers interposed therebetween; a first external electrode electrically connected to the first internal electrodes and a second external electrode electrically connected to the second internal electrodes; and a conductive paste layer formed on the first external electrode and the second external electrode, wherein the first and second external electrodes include a first conductive metal and glass, and the conductive paste layers include a second conductive metal.

10. The printed circuit board of claim 9, wherein, when length of the first and second external electrodes in a length direction of the ceramic body is denoted by A and length of the conductive paste layers in the length direction of the ceramic body is denoted by B, 0.8≦B/A≦1.0 is satisfied

11. The printed circuit board of claim 9, wherein the first conductive metal is at least one selected from the group consisting of copper (Cu), silver (Ag), nickel (Ni), and alloys thereof.

12. The printed circuit board of claim 9, wherein the second conductive metal is copper (Cu).
